(19) United States
(12) Patent Application Publication
(10) Pub. No.: US 2025/0311299 A1
(43) Pub. Date: Oct. 2, 2025

(54) ISOLATING BACKSIDE CONTACTS

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Oleg Gluschenkov, Tannersville, NY (US)

(21) Appl. No.: 18/619,879

(22) Filed: Mar. 28, 2024

(51) Int. Cl. H01L 29/423; H01L 21/8238; H01L 23/528; H01L 27/092; H01L 29/06; H01L 29/08; H01L 29/66; H01L 29/775; H01L 29/786

(52) U.S. Cl. CPC H10D 30/6735; H01L 23/5286; H10D 30/014; H10D 30/43; H10D 30/6757; H10D 62/118; H10D 62/151; H10D 64/017; H10D 64/021; H10D 84/0184; H10D 84/0186; H10D 84/038; H10D 84/85

(57) ABSTRACT

A sidewall spacer may adequately electrically isolate or separate a first backside contact from a second backside contact. As such, the first backside contact may be discrete from the second backside contact. The first backside contact may be formed in a first fabrication sequence and the second backside contact may be formed in a subsequent or sequential fabrication sequence. During the fabrication sequence of the second backside contact, the sidewall spacer may be formed. The sequential fabrication of the backside contacts and the sidewall spacer may provide for decreased pitch between the backside contacts which may allow for further semiconductor integrated circuit device scaling.

### BACKGROUND

A backside back-end-of-line (BEOL) network, such as a backside power distribution network (BSPDN) may include signal wires for signal routing and power wires for providing power potential (e.g., VDD, VSS, etc.). The backside BEOL network may allow for the distribution of power wires and signal wires between both the frontside and backside of the semiconductor IC device. The backside BEOL network may further allow for the full or partial decoupling of signal routing and/or power routing and/or allows for dividing or splitting power wires and/or signal wires between both the frontside and backside of the semiconductor IC device. By incorporating the backside BEOL network, routing congestion may be reduced, which may lead to further semiconductor integrated circuit (IC) device scaling. For example, semiconductor IC devices that incorporate a backside BEOL network can result in a 30% area reduction and improved current-resistance (IR) drop compared to typical semiconductor IC devices that include solely a frontside BEOL network.

### SUMMARY

In an embodiment of the present disclosure, a semiconductor integrated circuit (IC) device is presented. The semiconductor IC device includes a first transistor with a first source/drain (S/D) region and a second transistor with a second S/D region. The semiconductor IC device further includes a first backside contact directly coupled to a bottom surface of the first S/D region. semiconductor IC device further includes a second backside contact directly coupled to a bottom surface of the second S/D region. The semiconductor IC device further includes a sidewall spacer directly coupled to a sidewall of the first backside contact and directly coupled to a sidewall of the second backside contact.

In an embodiment of the present disclosure, another semiconductor integrated circuit (IC) device is presented. The semiconductor IC device includes a first transistor cell with a first pair of n-type transistors and a second transistor cell with a second pair of p-type transistors. The semiconductor IC device further includes a first backside contact directly coupled to a n-type source/drain (S/D) region of the first transistor cell. The semiconductor IC device further includes a second backside contact directly coupled to a p-type S/D region of the second transistor cell. The semiconductor IC device further includes a sidewall spacer directly coupled to a sidewall of the first backside contact and directly coupled to a sidewall of the second backside contact.

In an embodiment of the present disclosure, a semiconductor integrated circuit (IC) device fabrication method is presented. The method includes forming a first transistor that includes at least a first source/drain (S/D) region and forming a second transistor that includes at least a second S/D region that is adjacent to the first S/D region. The method further includes forming a first backside contact that is directly coupled to the first S/D region. The method further includes, after forming the first backside contact, forming a second backside contact opening underneath the second S/D region that removes a portion of the first backside contact. The method further includes forming a sidewall spacer that is directly coupled to the first backside contact within the second backside contact opening. The method further includes forming a second backside contact that is directly coupled to the second S/D region and that is directly coupled to the sidewall spacer.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1A depicts a cross-section view of a semiconductor IC device that includes one or more backside contacts that are directly coupled against a sidewall spacer, according to one or more embodiments of the disclosure.

FIG. 1B depicts a cross-section view of an illustrative backside contact, according to one or more embodiments of the disclosure.

FIG. 1C depicts a cross-section view of a neighboring backside contacts that are directly coupled against a same sidewall spacer, according to one or more embodiments of the disclosure.

FIG. 2 depicts a partial structure top-down view of an illustrative semiconductor IC device that includes one or more backside contacts that are directly coupled against a sidewall spacer, according to one or more embodiments of the disclosure.

FIG. 3 through FIG. 15 depict various fabrication structure cross-section views of an illustrative semiconductor IC device that includes one or more backside contacts that are directly coupled against a sidewall spacer, according to one or more embodiments of the disclosure.

FIG. 16 depicts a method of fabricating an illustrative semiconductor IC device that includes one or more backside contacts that are directly coupled against a sidewall spacer, according to one or more embodiments of the disclosure.

### DETAILED DESCRIPTION

Backside BEOL networks may be difficult to manufacture as they require structures of various microdevices, such as a transistor source, drain, and/or gate, to connect the backside wires of the backside BEOL network. Particularly, there are difficulties in fabricating adjacent backside contacts that connect microdevices to the backside BEOL network at smaller and smaller device sizes. In some implementations, the microdevices are so small that traditional lithography and etching techniques cannot fabricate contacts small enough to allow such contacts to connect to adjacent microdevices. In these instances, a merged contact that is shared by the adjacent microdevices may be undesirably necessary.

The embodiments of the present disclosure relate to fabrication methods and resulting structures for semiconductor devices. More specifically, the present disclosure relates to fabrication methods and resulting semiconductor integrated circuit (IC) devices that include one or more backside contacts that are directly coupled against a sidewall spacer. In some examples, the backside contacts may be sequentially fabricated. After the formation of a first backside contact, an associated backside contact opening is formed. The sidewall spacer may be formed within the backside contact opening and may be directly coupled to the first backside contact. Subsequently, the second backside contact may be formed within the backside contact opening and may be directly coupled to the sidewall spacer. The sidewall spacer may adequately electrically isolate the backside contacts. As such, the backside contacts may be electrically discrete or separate while still having a relatively small backside contact pitch therebetween.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, e.g., source-drain current, is controlled by a voltage applied to an associated gate. A FET typically has three terminals, e.g., a gate structure, a source region, and a drain region. A gate structure is a structure used to control output current (e.g., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, field programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The footprint area of a FET is related to the electrical conductivity of the channel material. If the channel material has a relatively high conductivity, the FET can be made with a correspondingly smaller footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

For some transistors, integration of the transistors with a backside back-end-of-line (BEOL) network is one of the key challenges to providing increasing packaged IC device densities and performance increases. By incorporating a backside BEOL network into the semiconductor IC device, routing congestion may be eased. Currently, there is a need for semiconductor IC device fabrication techniques to adequately electrically isolate backside contacts that have a relatively small backside contact pitch that may otherwise dictate a shared or merged backside contact.

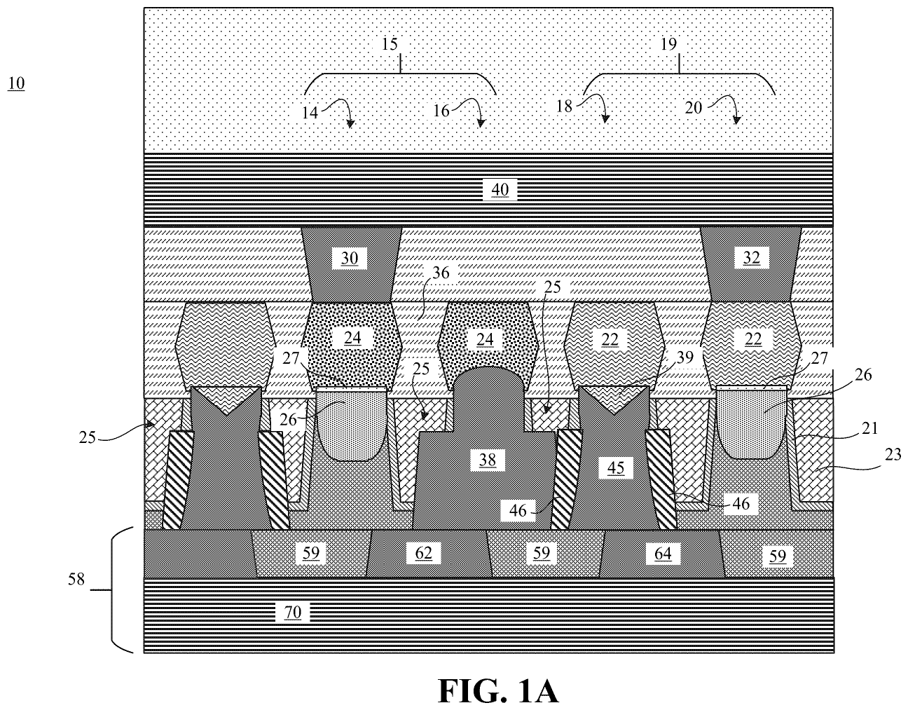

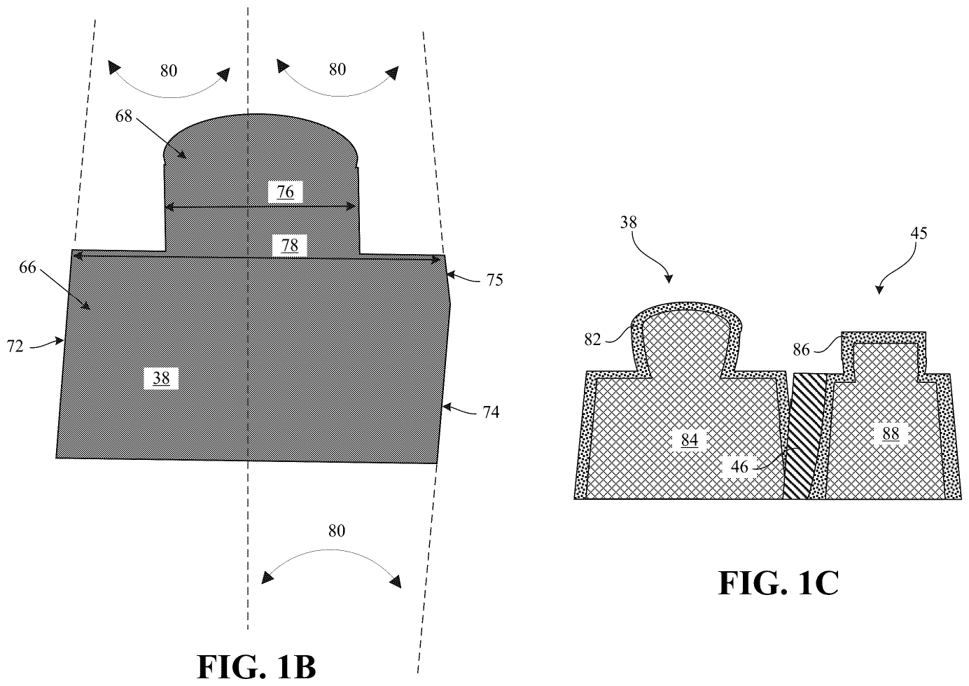

Referring now to FIG. 1A, a cross-sectional view of an illustrative semiconductor integrated circuit (IC) device 10 that includes adjacent backside contacts is depicted.

In an embodiment of the disclosure, the semiconductor IC device includes a first transistor 16 that has a first source/drain (S/D) region 24 and includes a second transistor 18 that includes a second S/D region (e.g., combined S/D region 22 and S/D region extension 39). The semiconductor IC device further includes a first backside contact 38 directly coupled to a bottom surface of the first S/D region 24 and further includes a second backside contact 45 directly coupled to a bottom surface of the second S/D region. The semiconductor IC device further includes a sidewall spacer 46 directly coupled to a sidewall of the first backside contact 38 and directly coupled to a sidewall of the second backside contact 45.

The backside contact 38 and the backside contact 45 may be sequentially formed, or in other words, may be formed in different fabrication stages. As a result, the backside contact 38 and the backside contact 45 may have relatively different geometries, may be composed of relatively different materials, or the like. The sidewall spacer 46 may be formed upon the sidewall(s) of a backside contact opening that is associated with the backside contact 45. This backside contact opening may remove a portion of the first formed backside contact 38. As a result, the sidewall spacer 46 may then be formed directly upon the backside contact 38. Subsequently, the backside contact 45 may be formed directly upon the sidewall spacer 46.

In embodiments, the sidewall spacer 46 may adequately electrically isolate or separate the backside contact 38 from the backside contact 45, or vice versa. As such, the backside contact 38 may be discrete from the backside contact 45. The utilization of the sequential fabrication of the backside contact 38 and the backside contact 45, in association with the sidewall spacer 46, may also provide for decreased pitch between the backside contact 38 and the backside contact 45 which may otherwise require a single backside contact to service otherwise separate transistors 16, 18.

In an example, the first S/D region 24 and the second S/D region (e.g., combined S/D region 22 and S/D region extension 39) are oppositely doped. For example, the first S/D region 24 may be a n-type S/D region and the second S/D region may be a p-type S/D region.

In an example, a top surface of the first backside contact 38 is above a top surface of the second backside contact 45. This may be the result of the formation of the S/D region extension 39 prior to the formation of the second backside contact 45 there against and/or the gouging of the first S/D region 24 prior to the formation of the first backside contact 38 there against.

In an example, the top surface of the first backside contact 38 is inset within the first S/D region 24. This may be the result of gouging of the first S/D region 24 prior to the formation of the first backside contact 38 there against.

In an example, a bottom surface of the second S/D region 22 is below a bottom surface of the first S/D region 24. This may be the result of the formation of the S/D region extension 39 prior to the formation of the second backside contact 45 there against.

In an example, a shallow trench isolation (STI) region 25 separates an upper portion 68, depicted in FIG. 1B, of the first backside contact 38 from an upper portion of the second backside contact 45 (e.g., the portion of the second backside contact 45 above the sidewall spacer 46). The STI region 25 may be above the sidewall spacer 46 and/or above a lower portion of the first backside contact 38 and below an interlayer dielectric (ILD) material 36 that surrounds the transistors 16, 18.

In an embodiment of the disclosure, another semiconductor IC device is presented. The semiconductor IC device includes a first transistor cell 15 comprising a first pair of n-type transistors 14, 16. The semiconductor IC device further includes a second transistor cell 19 comprising a second pair of p-type transistors 18, 20. The semiconductor IC device further includes a first backside contact 38 directly coupled to a n-type source/drain (S/D) region 24 of the first transistor cell 15. The semiconductor IC device further includes a second backside contact 45 directly coupled to a p-type S/D region (e.g., combined S/D region 22 and S/D region extension 39) of the second transistor cell 19. The semiconductor IC device further includes a sidewall spacer 46 directly coupled to a sidewall of the first backside contact 38 and directly coupled to a sidewall of the second backside contact 45.

As in the prior embodiment, the backside contact 38 and the backside contact 45 may be sequentially formed and may have relatively different geometries, may be composed of relatively different materials, or the like. The sidewall spacer 46 may be formed upon the sidewall(s) of a backside contact opening that is associated with the backside contact 45. This backside contact opening may remove a portion of the first formed backside contact 38. As a result, the sidewall spacer 46 may then be formed directly upon the backside contact 38. Subsequently, the backside contact 45 may be formed directly upon the sidewall spacer 46.

In embodiments, the sidewall spacer 46 may adequately electrically isolate or separate the backside contact 38 from the backside contact 45, or vice versa. As such, the backside contact 38 may be discrete from the backside contact 45. The utilization of the sequential fabrication of the backside contact 38 and the backside contact 45, in association with the sidewall spacer 46, may also provide for decreased pitch between the backside contact 38 and the backside contact 45 which may otherwise require a single backside contact to service otherwise separate transistors 16, 18.

In examples, as applied to both the embodiments, some other S/D regions 22, 24 that are not associated with the backside contacts 38, 45, may be connected to a frontside BEOL network 40 by a frontside contact 30, 32, respectively. These S/D regions 22, 24 may be directly coupled to a respective backside contact placeholder 26. Alternatively, as depicted, a barrier layer 27 may be between these S/D regions 22, 24 and the backside contact placeholder 26.

In examples, as applied to both the embodiments, a backside BEOL network 58 may be formed upon a backside of the semiconductor IC devices (e.g., upon the backside contacts 38, 45). The backside BEOL network 58 may include a wire 62 that is directly coupled to the backside contact 38 and a wire 64 that is directly coupled to the backside contact 45. The wire 62 and the wire 64 may be separated by and may be formed within a backside dielectric 59. Further levels 70 of the backside BEOL network 58 may exist on a backside of the semiconductor IC devices (e.g., upon the backside dielectric, upon the backside wires 62, 64).

The transistors 14 and 16 may be included within a cell 15 and may share a respective gate that is around and that contacts each of a respective series of vertically stacked channels of transistor 14, 16. Respective first end surfaces of respective vertically stacked channels may be connected to the S/D region 24 and distal end surfaces of respective vertically stacked channels may be connected to another S/D region (located in a plane that exists into or out of the page). In examples and as depicted, the S/D regions 24 within the cell 15 may be of the same type (e.g., P-type or N-type).

Transistors 18 and 20 may be included within a cell 19 and may share a respective gate that is around and that contacts each of a respective series of vertically stacked channels of transistor 18, 20. Respective first end surfaces of respective vertically stacked channels may be connected to the S/D region 22 and distal end surfaces of respective vertically stacked channels may be connected to another S/D region (located in the plane that exists into or out of the page). In examples and as depicted, the S/D regions within the cell 19 may be of the same type (e.g., P-type or N-type) S/D regions and may further be the opposite type relative to those S/D regions within cell 15.

Referring now to FIG. 1B, a cross-section view of an illustrative backside contact 38 is depicted. In an example, the first backside contact 38 includes a crescendoing sidewall 75 from vertical toward a bottom surface of the first backside contact 38 and a decrescendoing sidewall 74 from vertical toward the bottom surface of the first backside contact 38. The decrescendoing sidewall 74 may be formed by the backside contact opening utilized to form the sidewall spacer 46 and/or the second backside contact 45, depicted in FIG. 1A. The term “crescendoing sidewall” or the like is defined herein to be a sidewall angled from vertical with an orientation such that the sidewall is increasing in distance away from vertical toward a reference substantially horizontal surface, such as the bottom surface the applicable backside contact. The term “decrescendoing sidewall” or the like is defined herein to be a sidewall angled from vertical with an orientation such that the sidewall is decreasing in distance away from vertical toward a reference substantially horizontal surface, such as the bottom surface the applicable backside contact.

In an example, the sidewall spacer 46, depicted in FIG. 1A, is directly coupled to the decrescendoing sidewall 74 of the first backside contact 38. This may result from the decrescendoing sidewall 74 being exposed within the backside contact opening utilized to form the sidewall spacer 46 and/or the second backside contact 45, depicted in FIG. 1A.

In an example, the sidewall spacer 46, depicted in FIG. 1A, is indirectly coupled to the crescendoing sidewall 75 of the first backside contact 38. This may result in another material, such as STI region 25 being between the crescendoing sidewall 75 and the sidewall spacer 46.

In an example, e.g., when the first backside contact 38 has a circular, elliptical, or the like, top down shape, the crescendoing sidewall 75 may be the same sidewall as another crescendoing sidewall 72. Alternatively, e.g., when the first backside contact 38 has a quadrilateral, or the like, top down shape, the crescendoing sidewall 75 may be a distinct sidewall of the first backside contact 38 relative to the crescendoing sidewall 72.

In an example, the first backside contact 38 includes an upper portion 68 and a lower portion 66. Lower portion 66 may have a horizontal width 78 that is larger than a horizontal width 76 of the upper portion 68. This may be the result of the relative widths of the backside contact opening utilized to form first backside contact 38 in relation the width of the associated backside contact placeholder 26 that is removed to expose the first S/D region 24, as depicted in FIG. 1A. In an example, the crescendoing sidewall 72, crescendoing sidewall 75, and the decrescendoing sidewall 74 may have a same or substantially the same angle 80 from vertical.

Referring now to FIG. 1C, a cross-section view of an illustrative backside contact 38 is depicted. In an example, the first backside contact 38 includes one or more conductive liner layers 82 and a conductive filler 84 and the second backside contact 45 similarly includes one or more conductive liner layers 86 and a conductive filler 88. The conductive liner layer(s) 82, 86 may be a barrier liner, adhesion liner, or the like.

As the first backside contact 38 and the second backside contact 45 may be formed in different or sequential fabrication stages, the conductive liner layer(s) 82 and the conductive liner layer(s) 86 may be relative different materials. Similarly, the conductive filler 84 and the conductive filler 88 may be relative different materials. Alternatively, the conductive liner layer(s) 82 and the conductive liner layer(s) 86 may be substantially the same materials. Similarly, the conductive filler 84 and the conductive filler 88 may be substantially the same materials.

In an example, the sidewall spacer 46 is directly coupled to the conductive filler 84 and directly coupled to the conductive liner layer(s) 82. The sidewall spacer 46 being directly coupled to the conductive filler 84 of the first backside contact 38 may be the result of the backside contact opening exposing a portion of the conductive filler 84 of the first backside contact 38.

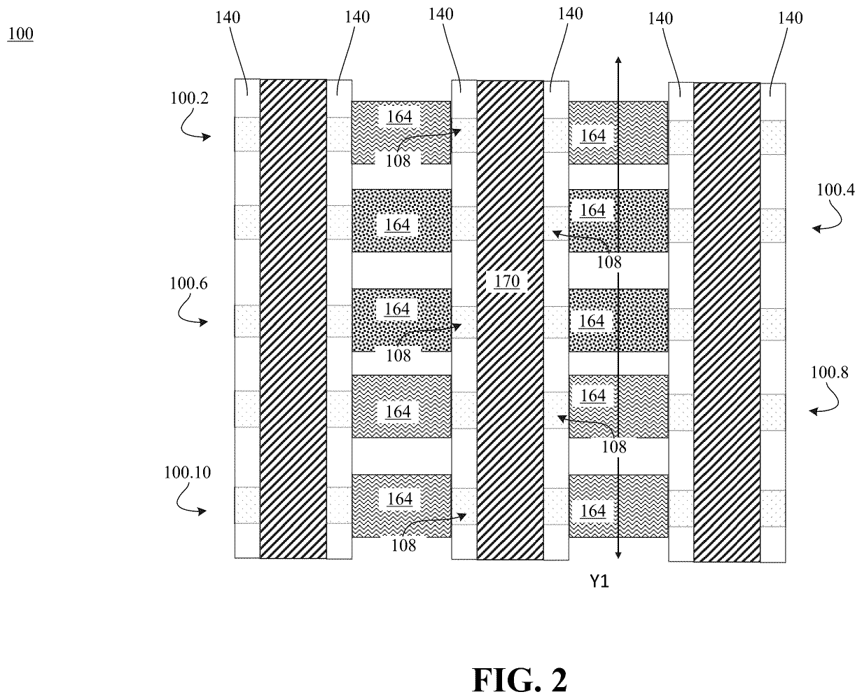

FIG. 2 depicts a partial structural top-down view of a semiconductor IC device 100 that is to include one or more backside contacts that are directly coupled against a sidewall spacer, according to one or more embodiments of the disclosure. Semiconductor IC device 100 includes transistors 100.2, 100.4, 100.6, 100.8, and 100.10. Each transistor 100.2, 100.4, 100.6, 100.8, and 100.10 may include a series of vertically stacked channels (e.g., a plurality of active semiconductor nanolayers 108 vertically stacked in various planes into and/or out of the page) between a respective source and/or drain (S/D) region (e.g., S/D regions 164). Transistors 100.2, 100.4, 100.6, 100.8, and 100.10. may share a replacement gate structure 170 that includes a conductive gate that is around and that contacts each of a series of vertically stacked channels of transistors 100.2, 100.4, 100.6, 100.8, and 100.10. A gate spacer 140 may contact and be against the replacement gate structure 170. An inner spacer may be located underneath the gate spacer and between adjacent vertically stacked channels and may adequately prevent shorting of the conductive gate with the S/D regions. In examples and as depicted, the S/D regions 164 within the transistors 100.2, 100.8, and 100.10 may be of the same type and the S/D regions 164 within the transistors 100.4, 100.6 may be of the same type and may further be the opposite type relative to those S/D regions 164 within the transistors 100.2, 100.8, and 100.10.

FIG. 2 also depicts a location of cross-sectional plane Y1, a vertical plane located between adjacent replacement gate structures 170 across various S/D region 164 of the transistors 100.2, 100.4, 100.6, 100.8, and 100.10.

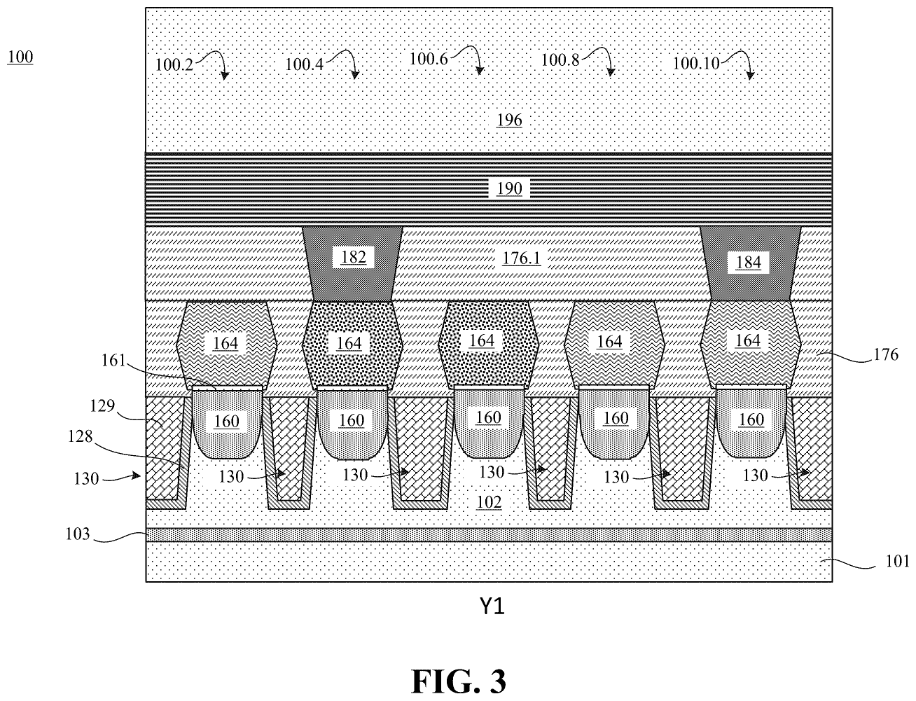

FIG. 3 depicts a cross-sectional view of a semiconductor IC device 100 that is to include one or more backside contacts that are directly coupled against a sidewall spacer. At this initial fabrication stage, the semiconductor IC device 100 may include a lower substrate 101, an etch stop layer 103, an upper substrate 102, STI regions 130, backside contact placeholders 160, barrier layers 161, S/D regions 164, a frontside ILD 176, a frontside contact ILD 176.1, a frontside contact 182, a frontside contact 184, a frontside BEOL network 190, and a carrier wafer 196. One or more of the various components depicted may be a part of a respective one or more adjacent or neighboring transistors 100.2, 100.4, 100.6, 100.8, and 100.10.

For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 3, such associated component numeral is expressly utilized. Otherwise, when components are referenced in the illustrative methodology that are not depicted in FIG. 3, a component numeral is not denoted.

The illustrative semiconductor IC device 100 may be formed by initially providing or forming a substrate structure. The substrate structure may be a bulk-semiconductor substrate. In one example, the bulk-semiconductor substrate may be a silicon-containing material. In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any suitable silicon-containing material(s), and the etch stop layer 103 may be a dielectric material with etch selectivity to one or both upper substrate 102 and/or the lower substrate 101. In one example, the etch stop layer 103 may be an oxide and the substrate structure may be referred to as a buried oxide (BOX) substrate. In a particular example, the lower substrate 101 may be composed of silicon. The etch stop layer 103 may be composed of Silicon Germanium (SiGe) and may be epitaxially grown from the top surface of lower substrate 101 and the upper substrate 102 may be composed of Si and may be epitaxially grown from the top surface of etch stop layer 103.

Next, the illustrative semiconductor IC device 100 may be formed by forming nanolayers over the substrate structure by forming a bottommost sacrificial nanolayer (not shown) and by forming a series of alternating sacrificial nanolayers (not shown) and active nanolayers (not shown) thereupon. In an implementation, the alternating active sacrificial nanolayer and active nanolayer (not shown) may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the bottommost sacrificial nanolayer and the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers, and the active nanolayers are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

The nanolayers may be patterned into nanolayer rows and shallow trench isolation (STI) regions 130 may be formed. To form the nanolayer rows, a mask layer may be formed on the uppermost nanolayer. The mask layer may be comprised of any suitable mask material(s). Utilizing photolithography and etching techniques, the mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure, or the like. Following the nanolayer stack patterning process, the one or more nanolayer rows are formed and the mask layer may be removed.

The removal of undesired portion(s) of the alternating nanolayers may further remove undesired portions of substrate structure that are adjacent to respective footprints of nanolayer rows to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer rows may utilize the etch stop layer 103 to stop the etch and form the bottom well of the one or more STI region openings.

A STI region 130 may be formed upon and/or within the substrate structure within respective STI region openings. The STI regions 130 may be formed by depositing electrical dielectric material(s) within respective STI region opening(s) that are adjacent to the one or more nanolayer rows. A top surface of the one or more STI regions 130 may be initially coplanar with or below a top surface of the substrate structure. In some implementations, further fabrication operations may generally remove portions of the STI regions 130 (e.g., sacrificial gate removal, replacement gate fabrication pre-clean, etc.), such that the top surfaces of the STI regions 130 are below the top surface of the substrate structure.

The one or more STI regions 130 may have a volume and/or geometry that sufficiently electrically isolates components or features of neighboring transistors 100.2, 100.4, 100.6, 100.8, and 100.10, or the like, may sufficiently electrically isolate neighboring nanolayer rows. For clarity, a particular STI region 130 may separate and adequately electrically isolate neighboring transistors 100.2, 100.4.

In an example, the STI region(s) 130 may be formed by depositing a STI liner 128 within the STI region openings. Subsequently, STI region(s) 130 may be further formed by depositing STI dielectric material 129 upon the STI liner 128. An etch back, recess, or the like, may occur to remove undesired or over formed STI liner 128 and/or STI dielectric material 129, such that the top surface of the STI region(s) 130 are coplanar with or below a bottom surface of the bottommost sacrificial nanolayer. STI liner 128 may be composed of but not limited to a nitride, low-K nitride (e.g., a nitride material with a lower dielectric constant relative to SiO₂), or the like. The STI dielectric material 129 may be composed of but not limited to an oxide, low-K oxide (e.g., an oxide material with a lower dielectric constant relative to SiO₂), or the like.

The illustrated semiconductor IC device 100 may be further fabricated by next forming sacrificial gate structures. The one or more sacrificial gate structures may be formed by patterning a gate cap layer, sacrificial gate layer, and sacrificial gate liner that are formed upon the nanolayers and STI regions 130 by, for example, using lithography and etch processes to remove undesired portions and retain desired portion(s), respectively. The retained desired portion(s) of the gate cap layer, sacrificial gate layer, and sacrificial gate liner may form a sacrificial gate liner, a sacrificial gate, and a sacrificial gate cap, respectively, of each of the one or more sacrificial gate structures. One or more sacrificial gate structures can be formed on targeted regions or areas of semiconductor IC device 100 to define the length of one or more GAA FETs and to provide sacrificial material for yielding targeted GAA FET structure(s) in subsequent processing.

The semiconductor IC device 100 may be further fabricated by forming gate spacers upon the sidewall(s) of the sacrificial gate structures, upon the STI region(s) 130, and around the one or more nanolayer rows. The semiconductor IC device 100 may be further fabricated by next forming source/drain (S/D) recesses within the one or more nanolayer rows between gate spacers of neighboring sacrificial gate structures. In other words, a single nanolayer row may be separated, by one or more S/D recesses, into multiple nanolayer stacks each located underneath at a portion of respective sacrificial gate structure and associated gate spacer. The undesired portions of sacrificial nanolayers, active nanolayers, and the like, may be removed by etching or other subtractive removal techniques. As the gate spacers and the sacrificial gate structures may be utilized to protect the underlying portions of sacrificial nanolayers and active nanolayers 108, respective sidewalls of the nanolayer rows may be substantially coplanar and substantially vertical with the outer sidewalls of the gate spacers there above.

As used herein, “substantially vertical” sidewalls deviate from a direction normal to a major surface (e.g., top surface, etc.) of the substrate 102 by less than 5°, e.g., 0°, 1°, 2°, 3°, 4°, or 5°, including ranges between any of the foregoing values.

The illustrated semiconductor IC device 100 may be further fabricated by forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The illustrated semiconductor IC device 100 may be further fabricated by forming a respective inner spacer within each indent. The one or more inner spacers can be formed by ALD or CVD or any other suitable deposition technique that deposits a dielectric material within the indent(s), thereby forming the inner spacer(s). In some examples, the inner spacer(s) are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s), an isotropic etch process is performed to create substantially vertical sidewalls of the inner spacer(s) that are coplanar with the substantially vertical sidewalls of the active nanolayers, of the gate spacers, and/or of the bottom isolation.

The illustrated semiconductor IC device 100 may be further fabricated by forming one or more backside contact placeholders 160 within the substrate structure in between adjacent sacrificial gate structures within a respective S/D recess. In one example, a respective backside contact placeholder 160 may be formed in all location(s) such that a respective backside contact placeholder 160 will be located underneath each S/D region 164.

The backside contact placeholders 160 may be formed by epitaxially growing an epitaxial material from exposed substrate structure surface(s) within respective S/D recesses. In some embodiments, epitaxial growth and/or deposition processes may be selective to forming on the semiconductor surfaces of the upper substrate 102, and may not deposit material on dielectric surfaces, such as silicon dioxide or silicon nitride surfaces of the STI regions 130. In some embodiments, the epitaxial growth of the one or more backside contact placeholders 160 may overgrow above the top surface of the substrate structure. In an example, the epitaxial material of the one or more backside contact placeholders 160 may be chosen to be etch selective to the material of the S/D region(s) 164, the material of the upper substrate 102, or the like. In another example, a barrier layer 161 (e.g., a Si epitaxially grown layer, or the like) may be formed upon the top surface of the backside contact placeholders 160. For example, the one or more backside contact placeholders 160 may be SiGe and a Si barrier layer 161 may be epitaxially grown from the top surface of the SiGe backside contact placeholders 160.

The illustrated semiconductor IC device 100 may be further fabricated by forming a respective S/D region 164 upon a respective backside contact placeholder 160. Each S/D region 164 may form either a source or a drain, respectively, of respective transistors 100.2, 100.4, 100.6, 100.8, and 100.10, and is connected to respective end surface of the active nanolayers of a nanolayer stack. Each S/D region 164 is composed of a semiconductor material and a dopant. As used herein, a “source/drain” region can be a source region or a drain region depending on subsequent wiring and application of voltages during operation of the applicable transistor. The semiconductor material that provides each of the S/D regions 164 may be composed of one of the semiconductor materials mentioned above for the semiconductor structure. For example, the semiconductor material that provides the S/D region 164 can be compositionally the same, or compositionally different from each active nanolayer. The dopant that is present in the S/D region 164 can be either a p-type dopant or an n-type dopant. The term “p-type” refers to the addition of impurities to an intrinsic semiconductor that creates deficiencies of valence electrons, and “n-type” refers to the addition of impurities that contributes free electrons to an intrinsic semiconductor.

The one or more S/D regions 164 may be epitaxially grown or formed. In some examples, the S/D region 164 are formed by in-situ doped epitaxial growth or an ex-situ process may be employed to introduce dopants into the S/D regions 164. Other doping techniques can be used to incorporate dopants in the S/D regions 164.

In some examples, the epitaxial growth that forms the S/D region 164 occurs or is promoted from the top surface of upper substrate 102, from the upper surface of backside contact placeholders 160 (or barrier layer 161 thereupon), or the like, and/or from the end surfaces of the active nanolayers, while epitaxial growth may be limited or does not occur from neighboring STI regions 130.

The illustrated semiconductor IC device 100 may be further fabricated by next forming interlayer dielectric (ILD) 176. For example, a blanket ILD 176 may be deposited over the S/D region(s) 164, over the STI region(s) 130, over the sacrificial gate structures, and over the gate spacers, and the like.

The ILD 176 can be any suitable material, such as, for example, porous silicates, carbon doped oxides, silicon dioxides, silicon nitrides, silicon oxynitrides, OPL, or other dielectric materials. In an example, the ILD 176 may be formed to a thickness above the top surface of the sacrificial gate structures. Subsequently, a planarization process, such as a CMP, may be performed to remove excess ILD 176 material and to remove the sacrificial gate caps of the sacrificial gate structures, thereby exposing the sacrificial gate thereunder. The planarization may also partially remove some of the sacrificial gates or may at least expose the sacrificial gate of the sacrificial gate structures.

The illustrated semiconductor IC device 100 may be further fabricated by removing the sacrificial gate structures and releasing the active nanolayers within the nanolayer stacks. The sacrificial nanolayers may be removed by a removal technique, such as one or more series of etches. For example, the etching can include a wet chemical etching process in which one or more chemical etchants are used to remove the sacrificial nanolayers.

The illustrated semiconductor IC device 100 may be further fabricated by forming a replacement gate structure (such as 170 shown in FIG. 2) in place of the removed sacrificial gate structures around the active nanolayers, upon STI region(s) 130, etc. Replacement gate structure(s) may be formed by initially forming an interfacial layer on the gate spacers, on the active nanolayers, on the bottom isolation, on the inner spacers, etc. that are interior to and/or upon the respective surfaces interior to the opening created by the removal of the sacrificial gate structure and the releasing of the active nanolayers. The interfacial layer can be deposited by any suitable techniques, such as ALD, CVD, PVD, thermal oxidation, combinations thereof, or other suitable techniques.

Replacement gate structure(s) may be further formed by forming a high-κ layer to cover the exposed surfaces of the interfacial layer. The high-κ layer can be deposited by any suitable techniques, such as ALD, CVD, metal-organic CVD (MOCVD), PVD, thermal oxidation, combinations thereof, or other suitable techniques. A high-κ material is a material with a higher dielectric constant than that of SiO₂. The replacement gate structure(s) may be further formed by depositing a work function (WF) gate upon the high-κ layer. The WF gate sets the threshold voltage (Vt) of the device. The high-κ layer may separate the WF gate from the nanolayer channel (e.g., active nanolayer). Other metals that may be desired to further fine tune the effective work function (eWF) and/or to achieve a desired resistance value associated with current flow through the gate in the direction parallel to the plane of the nanolayer channel.

The one or more replacement gate structure(s) may be further formed by depositing a conductive gate. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layer, the high-κ layer, the WF gate, or the like, are utilized in the replacement gate structures, the conductive gate may be formed upon the most recent structural formation thereof. The conductive gate can be comprised of a conductor material and/or metal, such as but not limited to, e.g., tungsten, aluminum, ruthenium, rhodium, cobalt, copper, tantalum, titanium, or the like. After the replacement gate structure 170 formation, the top surface of the semiconductor IC device 100 may be planarized by a planarization technique such as a CMP, mechanical grinding process, or the like.

The illustrated semiconductor IC device 100 may be further fabricated by next forming a frontside contact ILD 176.1. The frontside contact ILD 176.1 may be formed upon respective top surfaces of replacement gate structure(s), ILD 176, and gate spacers. The frontside contact ILD 176.1 may be formed by depositing a dielectric material, such as, for example, porous silicates, carbon doped oxides, silicon dioxides, silicon nitrides, silicon oxynitrides, or other dielectric materials. Any appropriate deposition technique for forming the frontside contact ILD 176.1 can be utilized. The frontside contact ILD 176.1 can be the same or different material(s) relative to the ILD 176.

The illustrated semiconductor IC device 100 may be further fabricated by next forming frontside contact 182 and frontside contact 184 within the frontside contact ILD 176.1. The frontside contact(s) 182, 184 may be formed by patterning respective frontside contact openings within frontside contact ILD 176.1 and/or ILD 176, respectively, from the frontside (e.g., from above the semiconductor IC device 100, as depicted, downward to respective structures thereof). The frontside contact(s) 182, 184 may be directly coupled to respective material(s) of one or more regions of the semiconductor IC device 100. For example, the illustrated frontside contact 182 is directly coupled with S/D region 164 of transistor 100.4 and the illustrated frontside contact 184 is in direct contact with S/D region 164 of transistor 100.10.

The frontside contact(s) 182, 184 may be formed by initially forming frontside contact opening(s). The frontside contact opening(s) may be formed by the same or shared lithography and etch process(es) or by sequential lithography and etch processes. The frontside contact(s) 182, 184 may be further formed by depositing conductive material such as metal into the respective frontside contact opening(s). In an example, frontside contact(s) 182, 184 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, conductive fill. Subsequently, the respective top surfaces of frontside contact(s) 182, 184 and the frontside contact ILD 176.1 may be substantially horizontal and/or substantially coplanar. In embodiments, the frontside contact(s) 182, 184 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

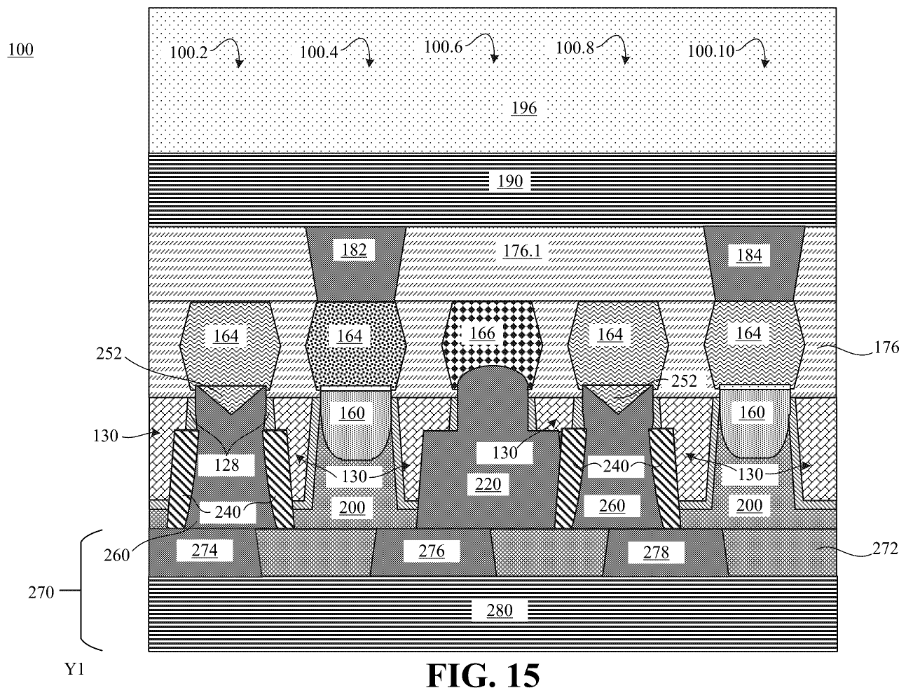

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 190 is formed on the frontside of the semiconductor device 100. Subsequently, a backside BEOL network 270, as depicted in FIG. 15, may be formed.

In the depicted example, the frontside BEOL network 190 is formed over the contact ILD 176.1 and upon the frontside contact(s) 182, 184. Respective wires within the frontside BEOL network 190 may be electrically connected to the one or more S/D regions 164, one or more replacement gate structure(s), or the like, by a respective frontside contact(s) 182, 184. For example, respective wire(s) within the frontside BEOL network 190 may be electrically connected to appropriate S/D regions 164 by frontside contact 182, and another and different group of respective wire(s) within the frontside BEOL network 190 may be electrically connected to appropriate replacement gate structures. In different implementations, the backside contacts 182, 184 may take the form of BEOL interconnects. In these implementations, respective wires within the frontside BEOL network 190 may be electrically connected to the one or more S/D regions 164, one or more replacement gate structure(s), or the like, by a lowest BEOL interconnect, such as a vertical interconnect access (VIA), that is within the frontside BEOL network 190.

The frontside BEOL network 190 may be located directly on the frontside surface of the MOL structure (e.g., contact ILD 176.1, frontside contact(s) 182, 184 etc.). The frontside BEOL network 190 can include one or more interconnect dielectric material layers (including one of the dielectric materials mentioned above for the frontside ILD 176) and contains metal wires (the metal wires can be composed of any electrically conductive metal or electrically conductive metal alloy) embedded therein. In some embodiments, the frontside metal wires within the frontside BEOL network 190 are composed of Cu. The frontside BEOL network 190 can include “x” numbers of frontside metal levels, wherein “x” is an integer starting from 1. The frontside BEOL network 190 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by bonding carrier wafer 196 to the frontside BEOL network 190. The carrier wafer 196 can include one of the semiconductor materials mentioned above for the semiconductor structure and the carrier wafer 196 may be attached to the semiconductor IC device 100 by a wafer-to-wafer bonding technique.

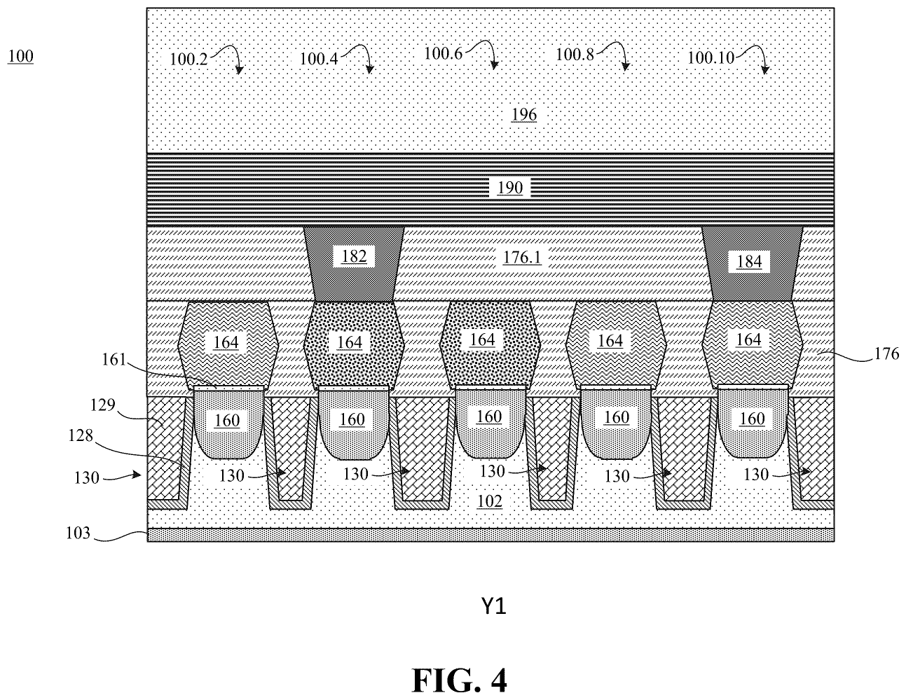

FIG. 4 depicts cross-sectional views of the semiconductor IC device 100 after fabrication operations, in accordance with embodiments of the present disclosure. In the depicted fabrication stages, the substrate structure may be recessed. For example, the lower substrate 101 may be removed and is therefore not shown in FIG. 4.

The substrate structure may be recessed by flipping the semiconductor IC device 100 and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

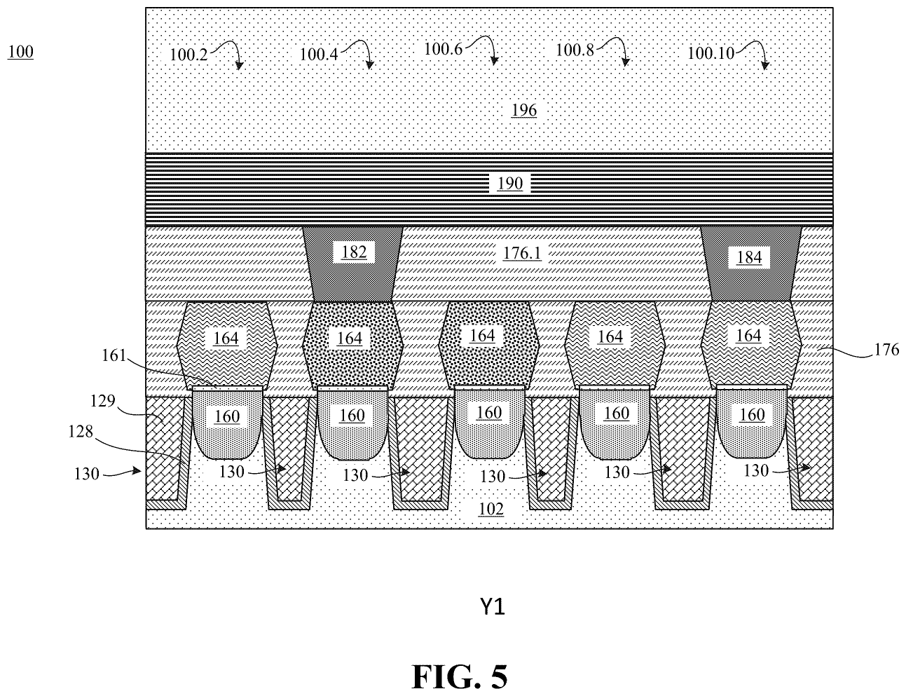

FIG. 5 depicts cross-sectional views of the semiconductor IC device 100 after fabrication operations, in accordance with embodiments of the present disclosure. In the depicted fabrication stages, the substrate structure may be further recessed. For example, etch stop layer 103 may be removed and is therefore not shown in FIG. 5.

The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

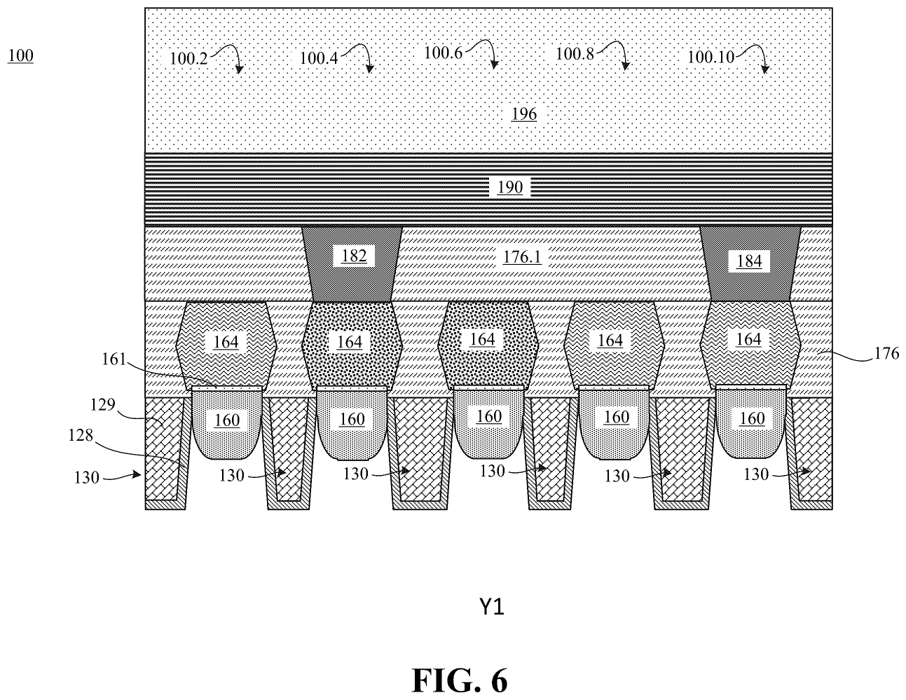

FIG. 6 depicts cross-sectional views of the semiconductor IC device 100 after fabrication operations, in accordance with embodiments of the present disclosure. In the depicted fabrication stages, the substrate structure may be further removed. For example, upper substrate 102 may be removed and is therefore not depicted in FIG. 6. The upper substrate 102 may be removed by an appropriate substrative removal technique, such as an etch, that removes associated portion(s) of the upper substrate 102. The etch may be timed or otherwise controlled to remove the material of substrate 102 selective to the STI regions 130, selective to the backside contact placeholders 160, or the like.

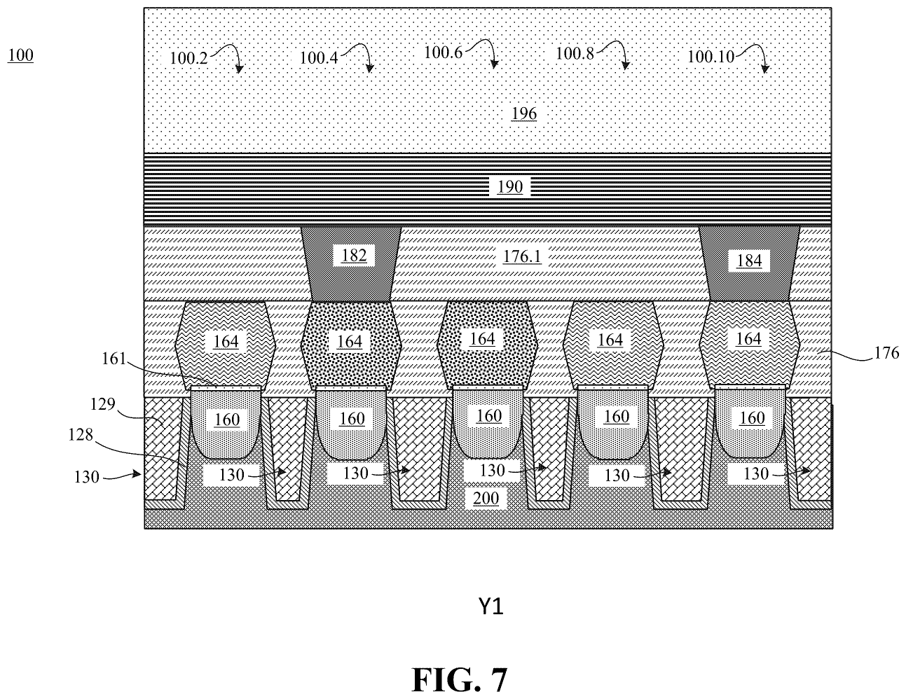

FIG. 7 depicts cross-sectional views of semiconductor IC device 100 shown after illustrative fabrication operation(s), in accordance with one or more embodiments. In the depicted fabrication stage, backside ILD 200 may be formed upon the exposed backside of the semiconductor IC device 100.

The backside ILD 200 may be formed upon the respective exposed backside surfaces of the STI regions 130, the backside contact placeholder(s) 160, or the like. The backside ILD 200 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 200 can be utilized. The backside ILD 200 can be formed using, for example, CVD, PECVD, ALD, flowable CVD, spin-on dielectrics, or PVD. In an example, the backside ILD 200 may be formed to a thickness below (as depicted) the bottom surface of the STI regions 130.

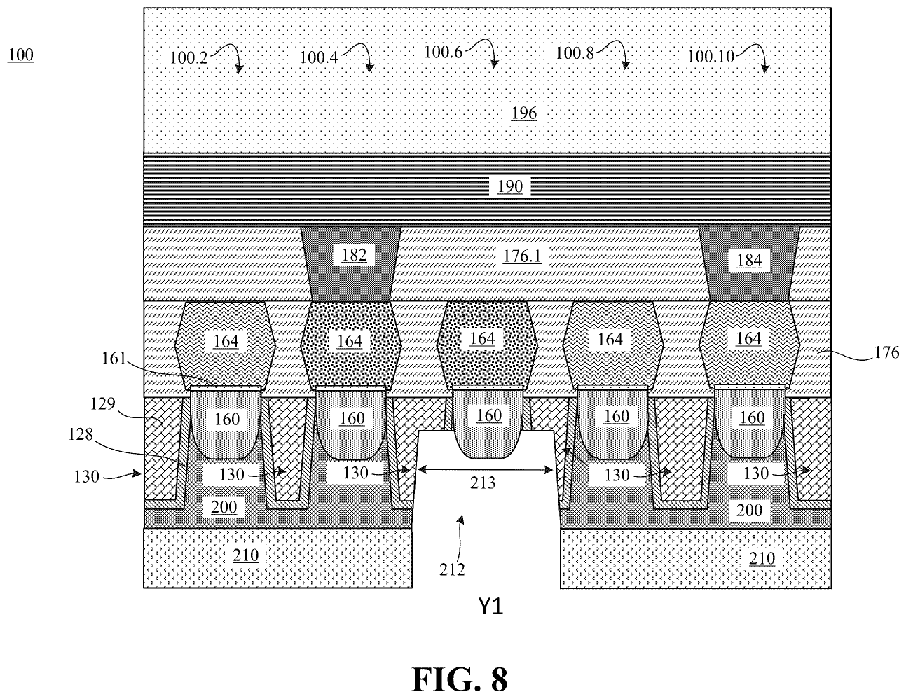

FIG. 8 depicts cross-sectional views of semiconductor IC device 100 shown after illustrative fabrication operation(s), in accordance with one or more embodiments. In the depicted fabrication stage, backside contact opening(s) 212 may be formed in a first series of backside contact fabrication stages.

The backside contact opening(s) 212 may be formed by lithography and etch process(es). In such process(es), a mask 210 may be applied to the backside of semiconductor IC device 100 and patterned. Openings in the patterned mask may be aligned with selected backside contact placeholders 160 to be removed while other protected portions of semiconductor IC device 100 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention. For example, the backside contact opening 212 may be formed by removing the materials of the backside ILD 200 and STI regions 130, selective to the material of the backside contact placeholder 160.

In an example, a placement of the backside contact opening 212 and a horizontal width 213 of the backside contact opening 212 may be chosen to expose a particular backside contact placeholder 160 without also exposing a relatively adjacent or neighboring backside contact placeholder 160, as depicted. In examples, the horizontal width 213 of the backside contact opening 212 may be relative greater than a similar width of a traditional backside contact opening. Further, the backside contact opening 212 may have a vertical depth, such that the well of the contact opening 212 may be located between the upper surface of the STI region(s) 130 and the lower surface of the STI region(s) 130.

The backside contact opening 212 may be formed to expose the and/or to partially remove a portion of the appropriate backside contact placeholder 160 there above (e.g., the backside contact placeholder 160 that is below a S/D region 164 that is not connected to the frontside BEOL network 190). The backside contact opening 212 may be further formed to expose the and/or to partially remove a portion of the STI regions 130 that are directly coupled to the exposed backside contact placeholder 160.

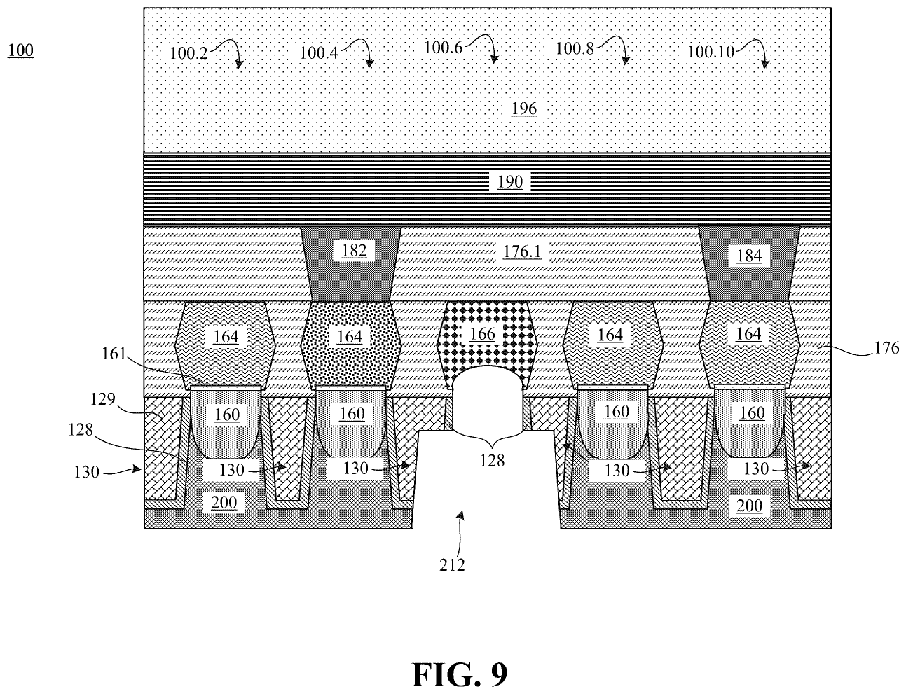

FIG. 9 depicts cross-sectional views of semiconductor IC device 100 shown after illustrative fabrication operation(s), in accordance with one or more embodiments. In the depicted fabrication stage, the backside contact placeholder(s) 160 that are exposed by a respective backside contact opening(s) 212 may be removed and are therefore not depicted in FIG. 9.

The backside contact placeholder(s) 160 that are exposed by respective backside contact opening(s) 212 may be removed by a substrative removal technique, such as an etch. In one example, the entire applicable contact placeholder(s) 160 may be removed. In another example, the lower portion of the backside contact placeholder is removed using the barrier layer 161 top surface of the backside contact placeholder 160 as an etch stop to protect the S/D region 164 there above. Optionally, respective barrier layer(s) 161 may also be removed thereby exposing at least a portion of the S/D region(s) 164 thereabove. Optionally, as depicted, the exposed S/D region(s) 164 may be gouged by a subtractive removal technique, such as an etch. In such process(es), dry and wet etching processes can have etching parameters that can be tuned, such as etchants used, etching temperature, etching solution concentration, etching pressure, source power, RF bias voltage, RF bias power, etchant flow rate, to promote the removal of the portion of S/D region(s) 164 that are undesired while also retaining the portion of the S/D region(s) 164 that are desired to be maintained.

Optionally, as depicted, the S/D region(s) 164 exposed by the removal of the backside contact placeholder 160 and barrier layer 161 may be locally doped to result in the doping concentration of this exposed S/D region 164 of transistor 100.6 being different than the doping concentration of the associated S/D region of transistor 100.4. (e.g., S/D regions of transistor 100.4 and 100.6 that are in a same cell). Due to the relative doping difference of this locally doped S/D region 164 of transistor 100.6, it is hereinafter referred to as S/D region 166.

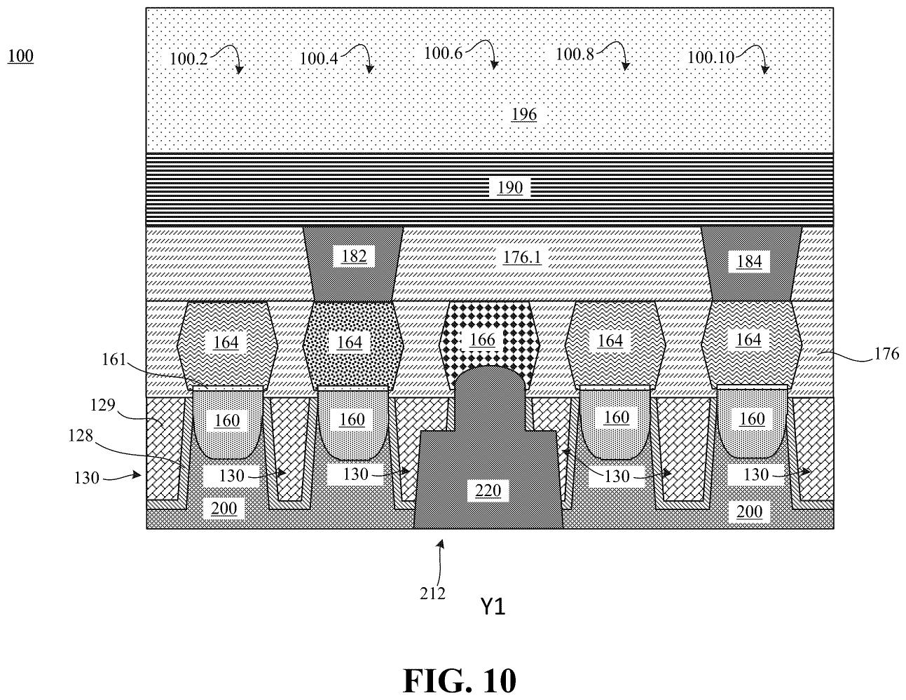

FIG. 10 depicts cross-sectional views of semiconductor IC device 100 shown after illustrative fabrication operation(s), in accordance with one or more embodiments. In the depicted fabrication stage, a respective backside contact 220 may be formed within a respective backside contact opening 212. Further in the depicted fabrication stage, a planarization process, such as a CMP process or a mechanical grinding process, may remove excess portions of the backside contact(s) 220.

The backside contact 220 may be formed within a respective backside contact opening 212 by depositing conductive material, such as metal, into the respective backside contact opening(s) 212. In an example, the backside contact(s) 220 may be formed by depositing a liner, such as Ni, NiPt or Ti, etc. onto the backside of semiconductor IC device 100 and into the backside contact opening(s) 212, depositing an adhesion liner, such as TiN, TaN, etc. upon the liner, and by depositing a conductive fill, such as Al, Ru, W, Co, Cu, etc. upon the adhesion liner. Subsequently, a planarization process may planarize the backside surface of the semiconductor IC device 100. As a result, the respective bottom surfaces of backside contact(s) 220 and backside ILD 200 may be substantially horizontal and/or substantially coplanar.

For clarity, the backside contact 220 is directly coupled with the associated S/D region there above. For example, the backside contact 220 is directly coupled with the S/D region 166, as depicted.

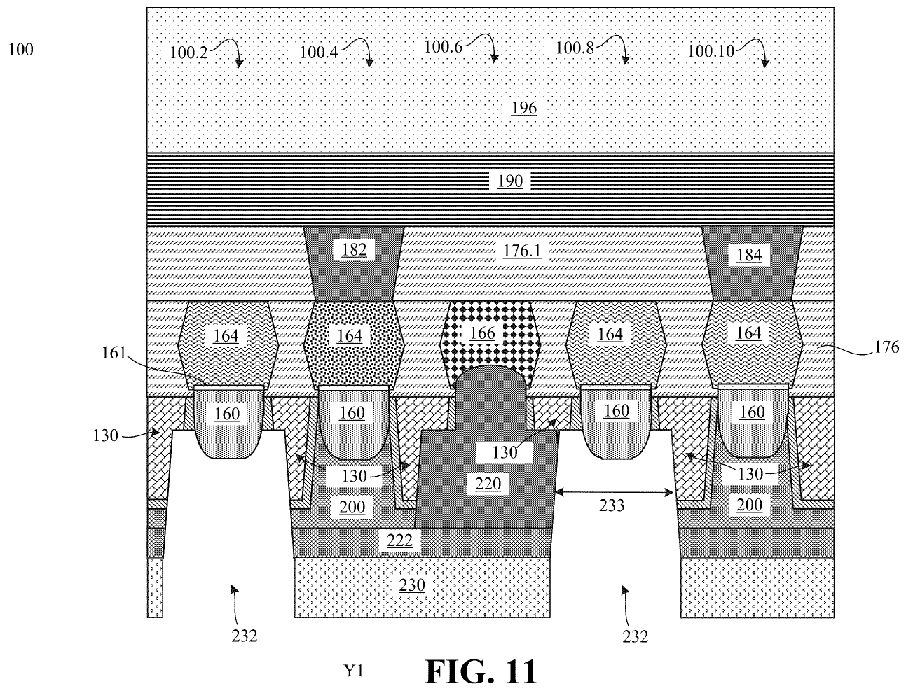

FIG. 11 depicts cross-sectional views of semiconductor IC device 100 shown after illustrative fabrication operation(s), in accordance with one or more embodiments. In the depicted fabrication stage, backside ILD 222 may be formed and backside contact opening(s) 232 may be formed in a second series of backside contact fabrication stages.

The backside ILD 222 may be formed upon the respective exposed backside surfaces of the backside ILD 200 and the backside contact(s) 220, and the like. The backside ILD 222 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 222 can be utilized. The backside ILD 222 can be composed of the same or different material(s) relative to the backside ILD 200.

The backside contact opening(s) 232 may be formed by lithography and etch process(es). In such process(es), a mask 230 may be applied to the backside of the backside ILD 222 and patterned. Openings in the patterned mask may expose the portion(s) of the underlying backside ILD 222, expose portions of the STI region(s) 130, expose the adjacent backside contact 220, and expose the portion(s) of the inline backside contact placeholder 160.

In an example, a placement of the backside contact opening 232 and a horizontal width 233 of the backside contact opening 232 may be chosen to expose a portion of the adjacent backside contact 220 and to expose a particular backside contact placeholder 160 without also exposing the adjacent or neighboring backside contact placeholder 160, as depicted. Further, the backside contact opening 232 may have a vertical depth, such that the well of the contact opening 232 may be located between the upper surface of the STI region(s) 130 and the lower surface of the STI region(s) 130. The vertical depth of the backside contact opening 232 may be relatively the same or different compared to the vertical depth of the backside contact opening 212, depicted in FIG. 8.

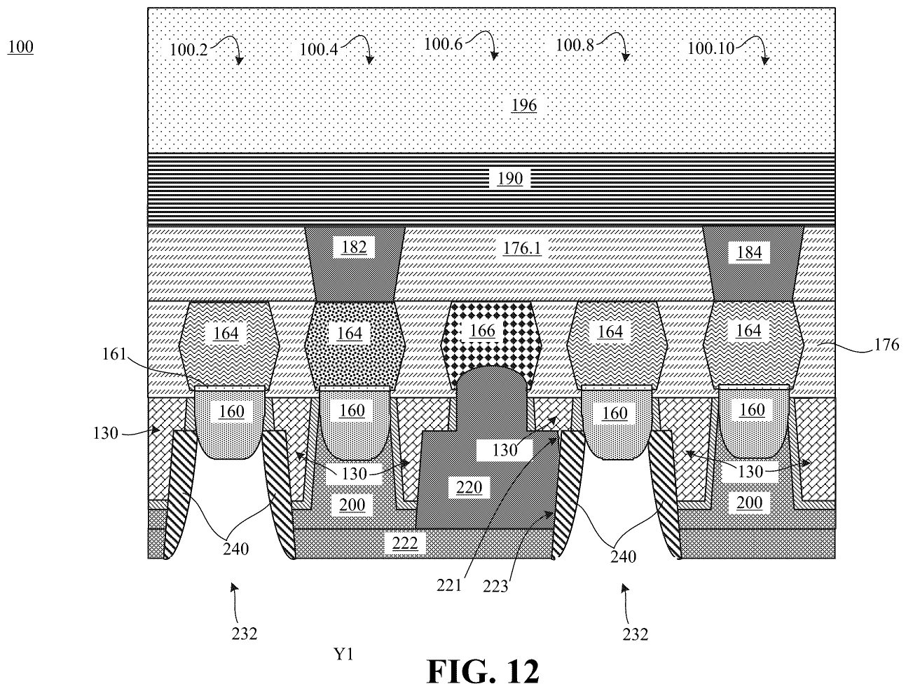

FIG. 12 depicts cross-sectional views of semiconductor IC device 100 shown after illustrative fabrication operation(s), in accordance with one or more embodiments. In the depicted fabrication stage, sidewall spacer(s) 240 may be formed upon respective sidewall(s) of the backside contact opening(s) 232.

The sidewall spacer(s) 240 may be formed by forming a conformal spacer material layer (not shown) on the backside ILD 222 and within the backside contact opening(s) 232, for example, by CVD or ALD. The conformal spacer material layer may be composed of a dielectric material that is different from the dielectric material of the backside ILD 200 and may be the same or different material relative to the material(s) of the STI regions 130. In one embodiment and when the backside ILD 200 includes a dielectric oxide, the conformal spacer material is a dielectric nitride. Examples of the dielectric nitride include, but are not limited to, silicon nitride, and silicon oxynitride. In other embodiments, conformal spacer material is composed of a low-K dielectric material, SiBCN, SiOCN, SiCO, etc. or any other suitable dielectric material. The thickness of the conformal spacer material layer can be from 3 nm to 20 nm, although lesser and greater thicknesses can also be employed.

Horizontal portions of the conformal spacer material layer are subsequently removed by an anisotropic etch, such as, for example, a RIE process. In such removal process, the horizontal portions of the conformal spacer material layer that are on the on the backside ILD 222 and the horizontal portions of the conformal spacer material layer that are on the backside contact placeholder 160 within the backside contact opening(s) 232 are removed. The remaining vertical portions of the conformal spacer material layer within the backside contact opening(s) 232 form the sidewall spacer(s) 240.

As a portion of the backside contact 220 is removed by the backside contact opening 232, the sidewall spacer 240 is formed in direct contact with the backside contact 220. Like the backside contact depicted in FIG. 1B, the backside contact 220 may include a crescendoing sidewall 221 from vertical toward a bottom surface of the backside contact 220 and a decrescendoing sidewall 223 from vertical toward the bottom surface of the backside contact 220. The decrescendoing sidewall 223 may be formed by the backside contact opening 232. The decrescendoing sidewall 223 may be the cut sidewall of the backside contact 220 that is formed by the backside contact opening 232. As such, the sidewall spacer 240 may be formed directly upon the decrescendoing sidewall 223.

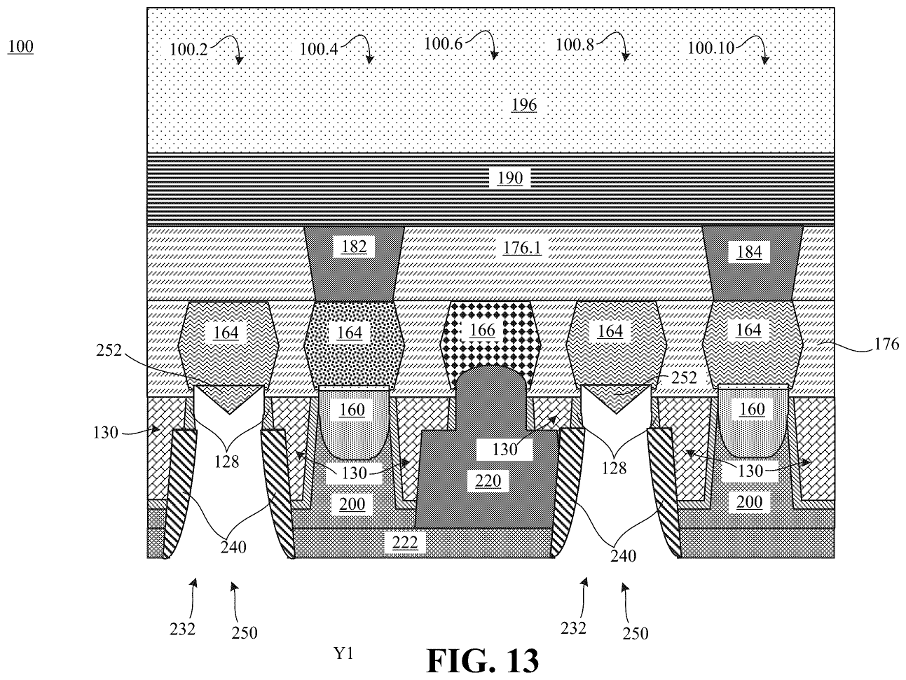

FIG. 13 depicts cross-sectional views of semiconductor IC device 100 shown after illustrative fabrication operation(s), in accordance with one or more embodiments. In the depicted fabrication stage, the backside contact placeholder(s) 160 that are exposed by a respective backside contact opening(s) 232 may be removed and are therefore not depicted in FIG. 13.

The backside contact placeholder(s) 160 that are exposed by respective backside contact opening(s) 232 may be removed by a substrative removal technique, such as an etch. In one example, the entire applicable contact placeholder(s) 160 may be removed. In another example, the lower portion of the backside contact placeholder is removed using the barrier layer 161 top surface of the backside contact placeholder 160 as an etch stop to protect the S/D region 164 there above. Optionally, respective barrier layer(s) 161 may also be removed thereby exposing at least a portion of the S/D region(s) 164 there above. Upon the removal of at least the backside contact placeholder 160 the backside contact opening 232 is enlarged and is hereinafter referred to as a backside contact opening 250.

Optionally, as depicted, a S/D extension region 252 may be formed from the S/D region(s) 164 that are exposed by the backside contact opening 250. For example, the S/D extension region 252 may be epitaxially grown from the backside exposed surface of the S/D region 164 that is exposed by the backside contact opening 250. The S/D extension region 252 typically forms a relatively larger S/D region and may be composed of the same semiconductor material and dopant relative to the S/D region 164. The relatively larger S/D region may be beneficial when S/D region 164 and the S/D extension region 252 of the transistor 100.8 form a p-type S/D region.

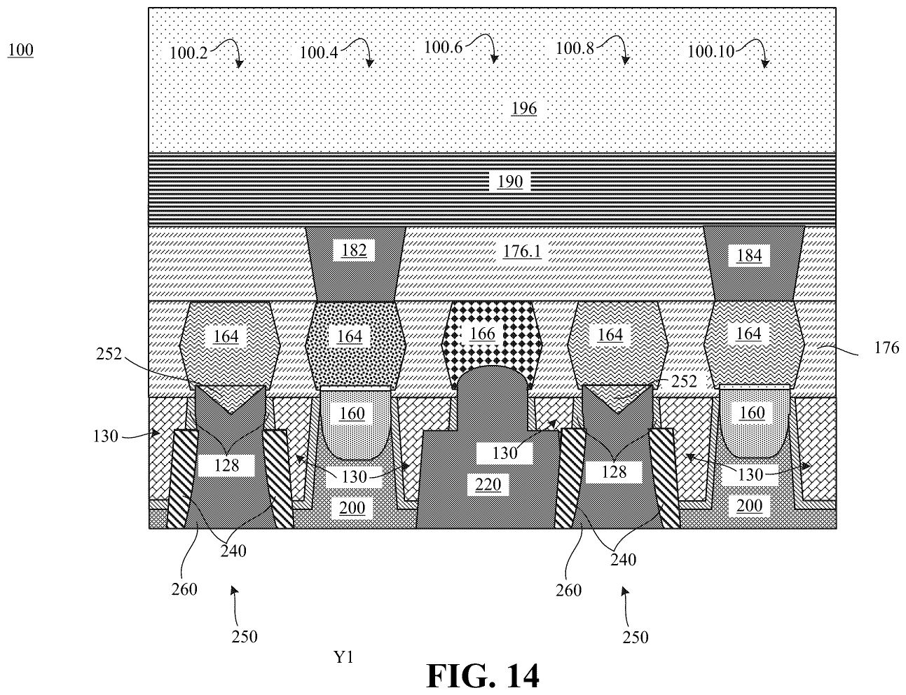

FIG. 14 depicts cross-sectional views of semiconductor IC device 100 shown after illustrative fabrication operation(s), in accordance with one or more embodiments. In the depicted fabrication stage, a respective backside contact 260 may be formed within a respective backside contact opening 250. Further in the depicted fabrication stage, a planarization process, such as a CMP process or a mechanical grinding process, may remove the backside ILD 222 and may remove excess portions of the backside contact(s) 260, sidewall spacers 240, backside ILD 200, and backside contact(s) 220.

The backside contact 260 may be formed within a respective backside contact opening 250 by depositing conductive material, such as metal, into the respective backside contact opening(s) 250. In an example, the backside contact(s) 260 may be formed by depositing a liner, such as Ni, NiPt or Ti, etc. onto the backside of semiconductor IC device 100 and into the backside contact opening(s) 250, depositing an adhesion liner, such as TiN, TaN, etc. upon the liner, and by depositing a conductive fill, such as Al, Ru, W, Co, Cu, etc. upon the adhesion liner. Subsequently, a planarization process may planarize the backside surface of the semiconductor IC device 100. As a result, the respective bottom surfaces of backside contact(s) 220, backside ILD 200, may be substantially horizontal and/or substantially coplanar.

For clarity, the backside contact 260 is directly coupled with the associated S/D region 164 there above. Further, as the backside contact(s) 260 are not formed in the same fabrication stages as the backside contact(s) 220, the backside contact(s) 260 may be composed of relatively different conductive material(s). Alternatively, though the backside contact(s) 260 are not formed in the same fabrication stages as the backside contact(s) 220, the backside contact(s) 260 may still be composed of the same relative conductive material(s). For further clarity, as the sidewall spacer(s) 140 effectively form a portion of the permitter of the backside contact opening 250, the backside contact 260 is formed directly upon the sidewall spacer(s) 140 therein.

FIG. 15 depicts cross-sectional views of semiconductor IC device 100 shown after illustrative fabrication operation(s), in accordance with one or more embodiments. In the depicted fabrication stage, a backside BEOL network 270 may be formed.

The backside BEOL network 270 may be formed over the backside ILD 200, over backside contact(s) 220, over backside contact(s) 260, and the like. The backside BEOL network 270 may be indirectly electrically and/or indirectly physically connected to the one or more S/D regions 164 by way of a particular backside contact(s) 220, 260. For example, as illustrated, a backside wire 274 (e.g., a backside power wire, backside power rail, etc.) within the backside BEOL network 270 may be connected the backside contact 260 of transistor 100.2. Similarly, a backside wire 276 (e.g., a backside power wire, backside signal wire, backside power rail, etc.) within the backside BEOL network 270 may be connected to S/D region 166 via backside contact 220 of transistor 100.6. Similarly, a backside wire 278 (e.g., a backside power wire, backside signal wire, backside power rail, etc.) within the backside BEOL network 270 may be connected to S/D region 164 via backside contact 260 of transistor 100.8.

The backside BEOL network 270 can include one or more interconnect dielectric material layers (such as layer 272 which may be composed of one or more of the dielectric materials mentioned above for the ILD 176) and contains backside conductive wires and/or interconnects, such as VIAs, embedded therein. Additional layers and/or levels of such dielectric material and metal layers are depicted as backside BEOL layers 280. In some embodiments, the backside wires within the backside BEOL network 270 are composed of Cu. The backside BEOL network 270 can include “x” numbers of backside metal levels, wherein “x” is an integer starting from 1. If not included in frontside BEOL network 190, backside BEOL network 270 may further contain conductive pads that are connected to one or more of the backside metal wires and may be used to connect the semiconductor IC device 100 to the external and/or higher-level structure.

In an example, signal routing and power routing is effectively split between the frontside BEOL network 190 and the backside BEOL network 270. For example, at least 90% of the frontside metal wires (e.g., furthest from the transistors 100.2, 100.4, 100.6, 100.8, and 100.10) are signal routing metal wires and the remainder frontside metal wires, which are usually present in metal levels closest to the transistors, can be used as power routing wires. Further in this example, at least 90% of the backside metal wires that are in metal levels closest to the transistors 100.2, 100.4, 100.6, 100.8, and 100.10 are power routing metal wires and the remainder backside metal wires, which are usually present in metal levels furthest away from the transistors 100.2, 100.4, 100.6, 100.8, and 100.10, can be used as signal routing wires. Power routing wires may be less dense than signal routing wires. A signal routing wire is defined herein as a conductive feature, such as a wire, interconnect, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 270 may be a backside power distribution network (BSPDN).

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

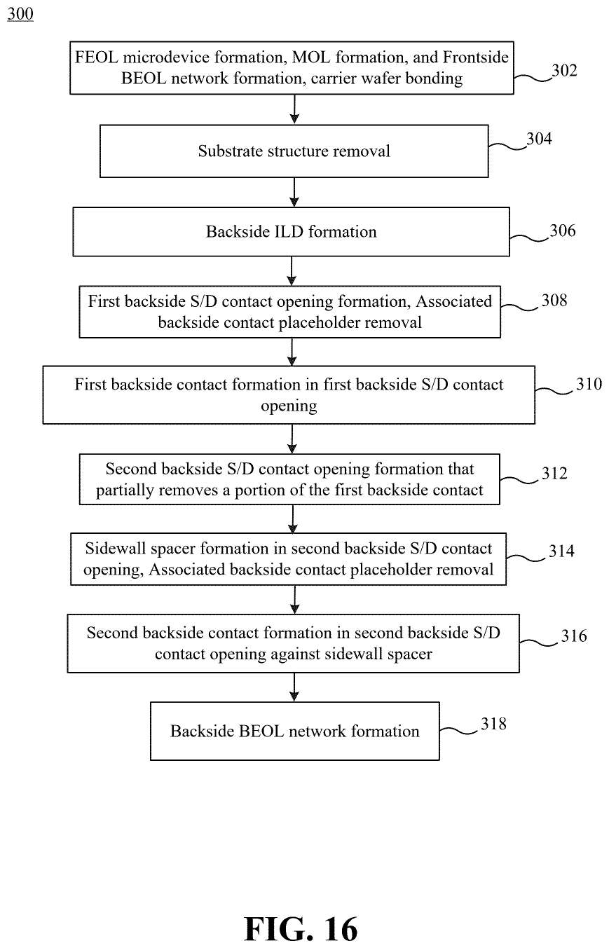

FIG. 16 depicts a flow diagram illustrating a method 300 to fabricate a semiconductor IC device, such as semiconductor IC device 100. The depicted fabrication operations of method 300 are illustratively depicted and described above with reference to one or more of FIG. 4 through FIG. 15 of the drawings, which describe the fabrication of semiconductor IC device 100, though the fabrication operations described in method 300 may be used to fabricate other semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming one or more front end of line (FEOL) microdevices, such as transistors, with forming middle of line (MOL) structures, such as frontside contact(s), with forming a frontside back end of line (BEOL) network, and with attaching a carrier wafer thereto. For example, one or more transistors, such as transistors 100.2, 100.4, 100.6, 100.8, and 100.10, are formed, one or more frontside contacts 182, 184 are formed that may contact components or regions, such as S/D regions 164 of transistors 100.4, 110.10, the frontside BEOL network 190 is formed upon the one or more frontside contacts 182, 184, and a carrier wafer 196 is bonded to the frontside BEOL network 190.

At block 304, the semiconductor IC device may be flipped, and a substrate associated with the FEOL microdevices may be removed. For example, the lower substrate 101 of the substrate structure may be removed, the etch stop layer 103 of the substrate structure may be removed, and the upper substrate 102 of the substrate structure may be removed.

At block 306, method 300 may continue with forming a backside ILD. For example, the backside ILD 200 may be deposited over the backside placeholders 160, over STI region(s) 130, or the like.

At block 308, method 300 may further continue with forming first backside contact openings and with removal of the backside contact placeholder(s) that are exposed thereby. For example, mask 210 is formed upon the backside of the semiconductor IC device 100 and is patterned to form backside contact opening(s) 212 so that selected backside contact placeholder 160 is exposed and subsequently removed.

At block 310, method 300 may further continue with forming a first backside contact within a respective first backside contact opening. For example, a backside contact 220 may be formed within a backside opening 212.

At block 312, method 300 may further continue with forming second backside contact opening(s) that remove or cut away a portion of the first backside contact. For example, mask 230 is formed upon the backside of the semiconductor IC device 100 and is patterned to form backside contact opening(s) 232 that cut or remove a portion of the backside contact(s) 220.

At block 314, method 300 may further continue with forming a sidewall spacer(s) within the second backside contact opening(s) and with removing an associated backside contact placeholder. For example, a sidewall spacer 240 is formed upon the sidewall(s) of and within a backside contact opening 232 and the associated backside contact placeholder 160 and barrier layer 161 (if present) may be removed to expose the inline S/D region 164 there above. The exposing of the inline S/D region 164 generally enlarges the backside contact opening 232 and this enlarged backside contact opening may be referred to herein as backside contact opening 250.

At block 316, method 300 may continue with forming a second backside contact within the second backside contact opening against the sidewall spacer and against the S/D region. For example, backside contact 260 may be formed within the backside contact opening 250 against the sidewall spacer 240 and against the associated S/D region (e.g., directly against the S/D region 164, directly against the S/D extension region 252, or the like). Subsequently, a CMP process may remove excess backside materials and may further planarize the backside of the semiconductor IC device.

At block 318, method 300 may continue with forming a backside BEOL network upon the backside of the semiconductor IC device. For example, backside BEOL network 270 may be formed upon the planarized backside of semiconductor IC device 100. A backside wire 276 within the backside BEOL network 270 may be directly coupled against the backside contact 220 and a backside wire 278 may be directly coupled against the backside contact 260.

For clarity, in an embodiment of the present disclosure, the method 300 may include forming a first transistor (e.g., transistor 100.6) that includes at least a first source/drain (S/D) region (e.g., S/D region 166) and forming a second transistor (e.g., transistor 100.8) that includes at least a second S/D region (e.g., a S/D region that includes S/D region 164 and S/D extension region 252) that is adjacent to the first S/D region. The method 300 may further include forming a first backside contact (e.g., backside contact 220) that is directly coupled to the first S/D region. The method 300 may further include, after forming the first backside contact, forming a second backside contact opening (e.g., backside contact opening 232) underneath the second S/D region that removes a portion of the first backside contact. The method 300 may further include forming a sidewall spacer (e.g., sidewall spacer 240) that is directly coupled to the first backside contact within the second backside contact opening. The method 300 may further include forming a second backside contact (e.g., backside contact 260) that is directly coupled to the second S/D region and that is directly coupled to the sidewall spacer.

In embodiments, the sidewall spacer 240 may adequately electrically isolate or separate the backside contact 220 from the backside contact 260, or vice versa. As such, the backside contact 220 may be discrete from the backside contact 260. The utilization of the sequential fabrication of the backside contact 220 and the backside contact 260, in association with the sidewall spacer 240, may also provide for decreased pitch between the backside contact 220 and the backside contact 260 which may otherwise require a single backside contact to service otherwise separate transistors 100.6, 100.8.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first transistor comprising a first source/drain (S/D) region and a second transistor comprising a second S/D region;
a first backside contact directly coupled to a bottom surface of the first S/D region;
a second backside contact directly coupled to a bottom surface of the second S/D region; and
a sidewall spacer directly coupled to a sidewall of the first backside contact and directly coupled to a sidewall of the second backside contact.

2. The semiconductor IC device of claim 1, wherein the first S/D region and the second S/D region are oppositely doped.

3. The semiconductor IC device of claim 2, wherein a top surface of the first backside contact is above a top surface of the second backside contact.

4. The semiconductor IC device of claim 3, wherein the top surface of the first backside contact is inset within the first S/D region.

5. The semiconductor IC device of claim 4 wherein a bottom surface of the second S/D region is below a bottom surface of the first S/D region.

6. The semiconductor IC device of claim 1, wherein the first backside contact comprises a crescendoing sidewall from vertical toward a bottom surface of the first backside contact and a decrescendoing sidewall from vertical toward a bottom surface of the first backside contact.

7. The semiconductor IC device of claim 6, wherein the sidewall spacer is directly coupled to the decrescendoing sidewall of the first backside contact.

8. The semiconductor IC device of claim 7, wherein the sidewall spacer is indirectly coupled to the crescendoing sidewall of the first backside contact.

9. The semiconductor IC device of claim 8, wherein a shallow trench isolation (STI) region separates the sidewall spacer from the crescendoing sidewall of the first backside contact.

10. The semiconductor IC device of claim 8, wherein the STI region further separates an upper portion of the first backside contact from an upper portion of the second backside contact.

11. A semiconductor integrated circuit (IC) device comprising:
a first transistor cell comprising a first pair of n-type transistors;
a second transistor cell comprising a second pair of p-type transistors;
a first backside contact directly coupled to a n-type source/drain (S/D) region of the first transistor cell;
a second backside contact directly coupled to a p-type S/D region of the second transistor cell; and
a sidewall spacer directly coupled to a sidewall of the first backside contact and directly coupled to a sidewall of the second backside contact.

12. The semiconductor IC device of claim 11, wherein a top surface of the first backside contact is above a top surface of the second backside contact.

13. The semiconductor IC device of claim 12, wherein the top surface of the first backside contact is inset within the first S/D region.

14. The semiconductor IC device of claim 13, wherein a bottom surface of the second S/D region is below a bottom surface of the first S/D region.

15. The semiconductor IC device of claim 11, wherein the first backside contact comprises a crescendoing sidewall from vertical toward a bottom surface of the first backside contact and a decrescendoing sidewall from vertical toward a bottom surface of the first backside contact.

16. The semiconductor IC device of claim 15, wherein the sidewall spacer is directly coupled to the decrescendoing sidewall of the first backside contact.

17. The semiconductor IC device of claim 16, wherein the sidewall spacer is indirectly coupled to the crescendoing sidewall of the first backside contact.

18. The semiconductor IC device of claim 17, wherein a shallow trench isolation (STI) region separates the sidewall spacer from the crescendoing sidewall of the first backside contact.

19. A semiconductor integrated circuit (IC) device fabrication method comprising:
forming a first transistor that includes at least a first source/drain (S/D) region and forming a second transistor that includes at least a second S/D region that is adjacent to the first S/D region;
forming a first backside contact that is directly coupled to the first S/D region;
after forming the first backside contact, forming a second backside contact opening underneath the second S/D region that removes a portion of the first backside contact;
forming a sidewall spacer that is directly coupled to the first backside contact within the second backside contact opening; and
forming a second backside contact that is directly coupled to the second S/D region and that is directly coupled to the sidewall spacer.

20. The semiconductor IC device fabrication method of claim 19, wherein the first backside contact comprises a crescendoing sidewall from vertical toward a bottom surface of the first backside contact and a decrescendoing sidewall from vertical toward a bottom surface of the first backside contact.
